(19) United States
(12) Patent Application Publication
(10) Pub. No.: US 2026/0261218 A1
(43) Pub. Date: Sep. 3, 2026

(54) PROGRAMMABLE POWER ARRAY ENERGY ROUTER

(71) Applicant: VIRGINIA TECH INTELLECTUAL PROPERTIES, INC., Blacksburg, VA (US)

(72) Inventors: Richard Zhang, Great Falls, VA (US); Yi-Hsun Hsieh, Blacksburg, VA (US); Shivani Harikesh Nair, Arlington, VA (US); William Chong, Ashburn, VA (US)

(21) Appl. No.: 19/531,301

(22) Filed: Feb. 5, 2026

Related U.S. Application Data
(60) Provisional application No. 63/754,074, filed on Feb. 5, 2025.
(60) Provisional application No. 63/782,054, filed on Apr. 2, 2025.

(51) Int. Cl. H02M 7/5387; H02M 7/00; H02M 7/493

(52) U.S. Cl. CPC H02M 7/53878; H02M 7/003; H02M 7/493

(57) ABSTRACT

An example modular field programmable power array (FPPA) system includes an FPPA cell including an alternating current (AC) port, a first (direct current) DC port, and a second DC port. The FPPA cell includes a transformer, an AC-side subcell coupled between the AC port and the transformer, a first DC-side subcell coupled between the first DC port and the transformer, and a second DC-side subcell coupled between the second DC port and the transformer. The FPPA system further includes an FPPA controller configured to control interconnections of the AC-side subcell, the first DC-side subcell, and the second DC-side subcell of the FPPA cell with a second FPPA cell.

### CROSS-REFERENCE TO RELATED APPLICATIONS

This application claims the benefit of and priority to U.S. Provisional Patent Application No. 63/754,074, filed Feb. 5, 2025, and U.S. Provisional Patent Application No. 63/782,054, filed Apr. 2, 2025, the entire contents of which are hereby incorporated herein by reference. This application is also related to Patent Cooperation Treaty (PCT) Application No. PCT/US26/13655, filed Feb. 3, 2026, the entire content of which is hereby incorporated herein by reference. This application is also related to U.S. Non-Provisional patent application (Attorney Docket No. 222204-1670), filed Feb. 5, 2026, and titled “HOUSING FOR PROGRAMMABLE POWER ARRAY ENERGY ROUTER,” the entire content of which is hereby incorporated herein by reference.

### BACKGROUND

Many electronic devices and systems rely upon power at a well-regulated, constant, and well-defined voltage for proper operation. In that context, power conversion devices and systems are relied upon to convert electric power or energy from one form to another. A power converter is an electrical or electro-mechanical device or system for converting electric power or energy from one form to another. As examples, power converters can convert alternating current (AC) power into direct current (DC) power, convert DC power to AC power, provide a DC to DC conversion, provide an AC to AC conversion, change or vary the characteristics (e.g., the voltage rating, current rating, frequency, etc.) of power, or offer other forms of power conversion. A power converter can be as simple as a transformer, but many power converters have more complicated designs and are tailored for a variety of applications and operating specifications.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 depicts an example high-voltage direct-current (HVDC) converter station according to various embodiments of the present disclosure.

FIG. 2A depicts a schematic of an example FPPA cell according to various embodiments of the present disclosure.

FIG. 2B depicts a schematic of an example FPPA system with insulated magnetic energy coupler (IMEC) according to various embodiments of the present disclosure.

FIG. 3A depicts switch realizations for AC-side subcells in the FPPA systems shown in FIGS. 2A and 2B according to various embodiments of the present disclosure.

FIG. 3B depicts representative operating states of a back-to-back MOSFET four-quadrant AC switch for AC-side subcells according to various embodiments of the present disclosure.

FIG. 3C depicts example AC switch bridge realizations for AC-side subcells and a simplified AC switch bridge defining terminal reference directions and bridge variables used for state classification according to various embodiments of the present disclosure.

FIG. 3D depicts example operating principles and switch realizations for AC-side subcells according to various embodiments of the present disclosure.

FIG. 4A depicts a switching period timing diagram showing duty cycle overlaps for switches for the AC-side subcells according to various embodiments of the present disclosure.

FIG. 4B depicts representative waveforms over a line cycle with respect to the FPPA systems shown in FIGS. 2A and 2B according to various embodiments of the present disclosure.

FIG. 5 depicts a control loop diagram for pulse-width modulation (PWM) generation for an FPPA cell according to various embodiments of the present disclosure.

FIG. 6 depicts a schematic of an example multi-phase FPPA system according to various embodiments of the present disclosure.

FIG. 7 depicts switch interconnect fabric of the multi-phase FPPA system shown in FIG. 6 for interconnecting AC-side subcells among multiple FPPA cells to each other and DC-side subcells among multiple FPPA cells to each other, according to various embodiments of the present disclosure.

### DETAILED DESCRIPTION

A high voltage direct current (HVDC) converter station is a terminal facility that converts electrical power between alternating current (AC) and direct current (DC) so that electricity can be transmitted over HVDC transmission lines or cables and then converted back to AC at the receiving end. State-of-the-art (SOTA) or some HVDC converter stations rely on modular multi-level converters (MMCs) for enabling DC transmission networks, interconnecting AC and DC grids, integrating renewable energy, and isolating grid disturbances. MMC converters rely on low frequency or line frequency transformers, which can impose large system size and weight with additional transportation and installation constraints. MMC converters also use arm inductors to limit circulating currents, and help to protect the converter during transients and faults. These arm inductors can be heavy, bulky, and expensive and cause power losses, reduced converter efficiency, and generation of extra heat that must be dissipated.

HVDC systems can be better suited than AC systems for transmitting high power levels over longer distances. With suitable components and hardware, HVDC systems can provide significantly greater power delivery at higher efficiency and density compared to AC systems. Although HVDC converter stations can initially cost more than AC substations with transformers, after a distance threshold, the total cost of HVDC systems may be lower than the total cost of AC systems due to lower cost of DC transmission lines than AC transmission lines. HVDC systems can provide reduced transmission losses, eliminate reactive power flow, and offer enhanced controllability of power transfer, especially for long-distance overhead and offshore transmission with submarine cable involving wind farms, offshore AC substations, offshore HVDC converter stations, and the like.

Some HVDC converter stations rely on single-input single-output (SISO) converters, such as MMC converters, which require more advanced protection and control for use in multi-terminal (MT) HVDC systems. Multi-terminal and/or meshed DC grids with SISO HVDC converters can increase cost, control complexity, protection complexity, and points of failure, while also reducing efficiency.

These HVDC converter stations also rely on valve module/submodule (VSM) capacitors, where capacitor size is driven by the single-phase ripple power handled, often leading to bulky designs that can exceed 60 percent of VSM volume. Additionally, some HVDC converter stations rely on inefficient insulation means for valves, such as by using air insulation from ground, thereby significantly increasing space requirements in various dimensions.

In the context outlined above, multi-input multi-output (MIMO) converters for HVDC systems are disclosed according to various embodiments. MIMO converters have not been deployed in HVDC systems due to complex control requirements and other technical challenges, and the embodiments disclosed in the present disclosure offer advancements in technology to help realize such concepts. MIMO converters for HVDC systems are realized in various ways, such as by implementing modular field programmable power array (FPPA) systems which can be controlled for fault-tolerant operation through bypass mechanisms at the cell and VSM levels and dynamic reconfiguration and programmability for power flow rerouting among AC and DC ports.

The FPPA systems of the embodiments are single-stage power converters with high-frequency isolation and designed to enable a multi-port energy router for the creation of multi-terminal DC macro grids and seamless interconnection with a bulk AC grid. A basic building block is referred to herein as an FPPA cell (also referred to herein as “cell” for short), which is a multi-port single-stage direct AC/DC/DC or AC/AC/DC power converter with high-frequency galvanic isolation that has the capability to couple at least one AC port and at least one DC port. The energy flows among the three ports can be magnetically coupled through a high-frequency transformer that includes an insulated magnetic energy coupler (IMEC). The IMEC enables a modular and ultra-high-power-density solution with uniformly distributed voltage stresses for building blocks at the AC and DC ports.

An FPPA cell may be implemented as a submodule, which can be stacked to form a module. A submodule may be encapsulated in bulk ceramic housing that provides excellent electrical insulation barriers and thermal conductive paths. A water jacket with a highly efficient milli-channel water cooling design can be embedded inside the ceramic housing to remove the heat generated from power losses. High voltage insulation barriers between the AC and DC ports are achieved through high dielectric strength polyimide layers in IMEC.

Compared with conventional MMC-based HVDC converters, the FPPA-based multi-port HVDC converter or energy router of the embodiments can achieve an ultra-high-power density in footprint and volume as the result of replacing line-frequency transformers with high-frequency transformers, eliminating bulky single-phase capacitors in each VSM, eliminating arm inductors, and replacing air insulation with high-dielectric strength polyimide layers and bulk ceramic housing between FPPA cells, VSMs, VMs, and/or valves.

According to one example, a modular field programmable power array (FPPA) system includes an FPPA cell including an alternating current (AC) port, a first (direct current) DC port, and a second DC port. The FPPA cell includes a transformer, an AC-side subcell coupled between the AC port and the transformer, a first DC-side subcell coupled between the first DC port and the transformer, and a second DC-side subcell coupled between the second DC port and the transformer. The FPPA system further includes an FPPA controller configured to control interconnections of the AC-side subcell, the first DC-side subcell, and the second DC-side subcell of the FPPA cell with a second FPPA cell.

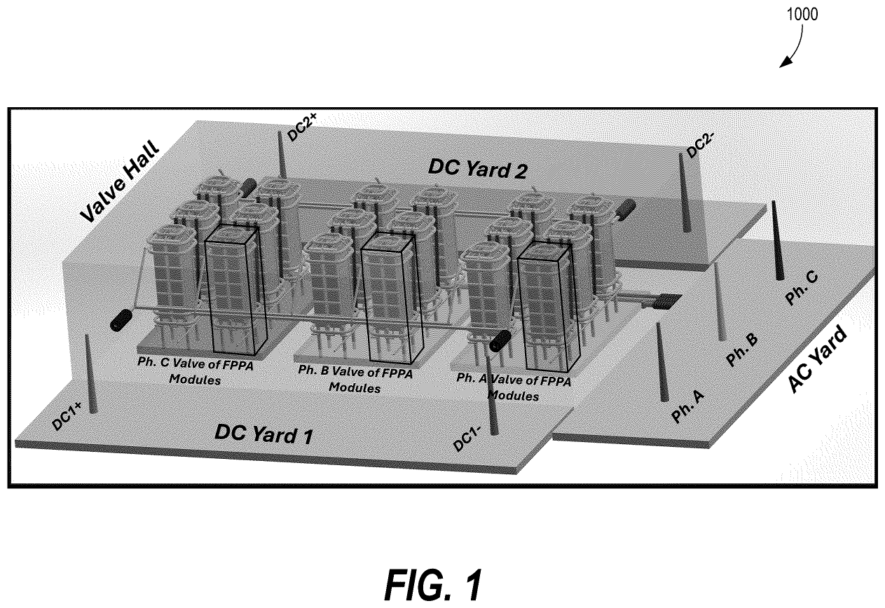

Referring now to the drawings, FIG. 1 depicts an example HVDC converter station 1000 according to various embodiments. The HVDC converter station 1000 is not exhaustively illustrated, meaning that one or more components not shown can be relied upon in some cases. Alternatively, one or more components can be omitted in practice although shown. The HVDC converter station 1000 includes an AC yard and two DC yards (e.g., DC yard 1 and DC yard 2). The HVDC converter station 1000 can interface with a three-phase AC system (e.g., bulk AC grid) through the AC yard, as indicated by Phase A, Phase B, and Phase C. For example, the HVDC converter station 1000 can include three phase legs for interfacing with the three-phase AC system. Although a three-phase AC system is shown, the HVDC converter station 1000 is not limited thereto and can interface with AC systems greater than or less than three phases. For example, the HVDC converter station 1000 can interface with a single-phase AC system via a single phase leg.

The HVDC converter station 1000 can interface with DC grids via the DC yards. In one example, the HVDC converter station 1000 can support approximately ±525 kV DC at ports of each DC yard. The HVDC converter station 1000 can be configured as a multi-port HVDC converter or energy router on HV DC grids and can be created with FPPA submodules, which can be stacked to form an FPPA module. FPPA submodules can be stacked as an FPPA module in a tower, and multiple towers can be implemented as valves in a valve hall as shown. In the example shown in FIG. 1, the HVDC converter station 1000 includes six towers in each phase leg, but the six towers are shown for illustrative purposes only.

The HVDC converter station 1000 can be used for the creation of macro-DC grids and seamless interconnection with existing bulk AC grids. The HVDC converter station 1000 is a modular HVDC converter station. For example, the HVDC converter station 1000 can include addition or removal of submodules, modules, valves, and phase legs, etc. The HVDC converter station 1000 incorporates single-stage direct AC/DC/DC power conversion topology using FPPA features, such as dynamic reconfigurability and programmability of power flow among DC and AC ports, fault-tolerant operation through bypass mechanisms at the FPPA cell and VSM levels, and advanced fault protection via current limiting and foldback functionalities at both the AC and DC ports.

The macro-DC grid's system architecture and energy flow across multiple AC and DC ports can be dynamically programmed in the field. The FPPA features of the HVDC converter station 1000 can include a control bandwidth more than 100 times greater than that of conventional MMC-based HVDC converters, enabled by silicon carbide (SiC) metal-oxide-semiconductor field-effect transistor (MOSFET) modules and high-frequency transformers within each FPPA cell, VSM, and VM according to one example. This enhanced control capability allows for the seamless implementation of advanced control, protection functions, and ancillary services for the bulk AC grid. As a result, the HVDC converter station 1000 significantly improves the operability, stability, and resilience of both the macro-DC grid and the interconnected AC counterpart.

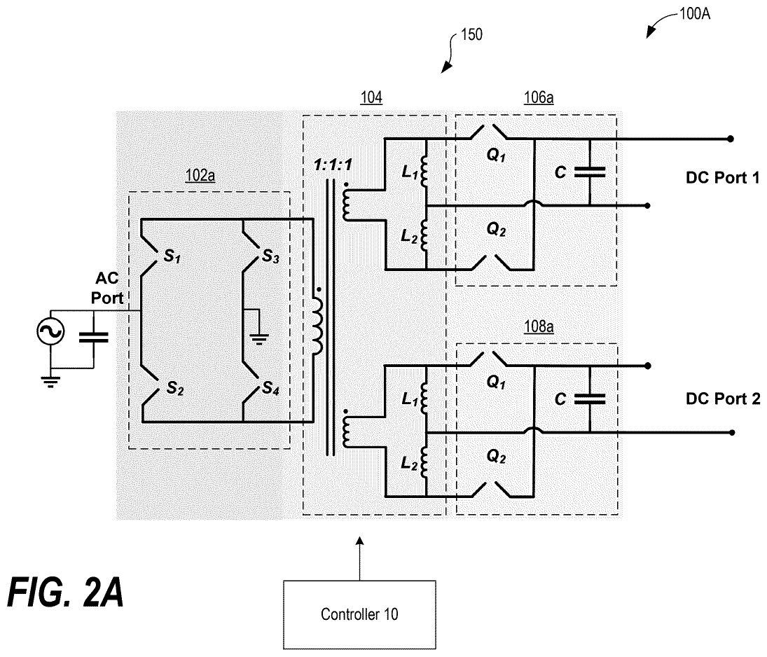

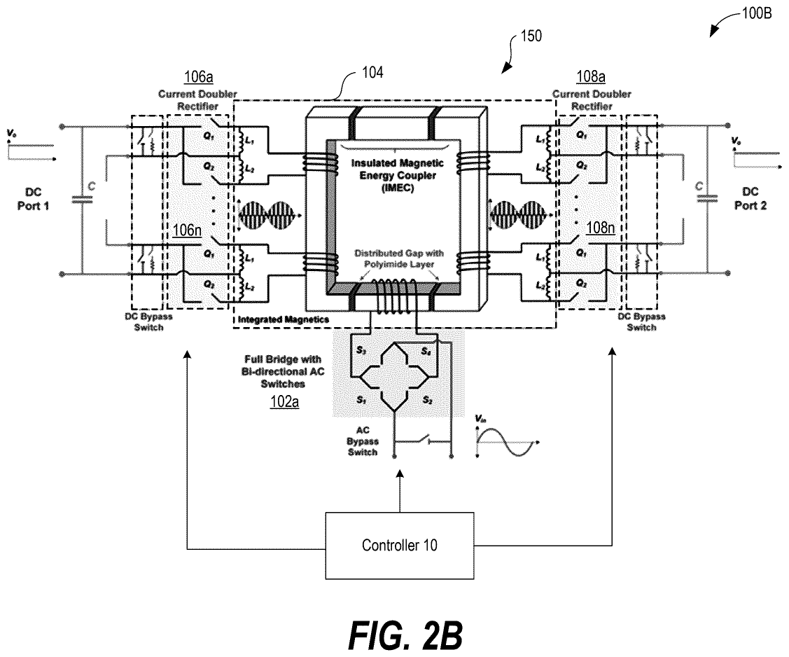

FIG. 2A depicts a schematic of an example FPPA system 100A including an FPPA cell 150, and FIG. 2B depicts a schematic of an example FPPA system 100B with insulated magnetic energy coupler (IMEC), according to various embodiments. The FPPA system 100A includes an FPPA cell 150 (also referred to herein as “cell 150”), which can be configured for single-phase operation within the HVDC converter station 1000 or MVDC power converter systems and can include a single stage direct MVAC to LVDC converter topology with galvanic isolation. In some embodiments, the FPPA cell 150 can be used for MVDC applications with MVDC power converter systems. In this sense, the FPPA cell 150 is suitable for both HVDC and MVDC power converter systems and applications. The FPPA cell 150 can be configured to provide single stage direct conversion with bidirectional or in some cases unidirectional power flow. The FPPA cell 150 can be implemented as a submodule of a phase leg in the HVDC converter station 1000, and the HVDC converter station 1000 can be operable with implementation of the FPPA cell 150 for single-phase operation.

In the example shown in FIG. 2A, the FPPA cell 150 includes a transformer 104, an AC-side subcell 102a coupled to a primary winding of the transformer 104 and the AC port, a DC-side subcell 106a coupled to a secondary winding of the transformer 104 and DC port 1, and a DC-side subcell 108a coupled to the secondary winding and DC port 2. Each of the DC-side subcells 106a and 108a can include bidirectional switches Q1 and Q2. Although two DC-side subcells are shown for the FPPA cell 150, the FPPA cell 150 can include only one DC-side subcell coupled to a DC port to facilitate AC/AC/DC conversion. In this sense, the FPPA cell 150 can include one or more AC-side subcells and one or more DC-side subcells for various MVDC or HVDC applications.

The AC-side subcell 102a can include bidirectional switches S1, S2, S3, and S4. A “subcell” as used herein refers to the lowest level modular building block in an FPPA cell and can include various types of switch bridges (e.g., full-bridge with bidirectional switches, half-bridge with bidirectional switches, and other types of bridge configurations) on the AC-side or various types of rectifiers (e.g., half-bridge or full-bridge rectifiers with diodes, unidirectional active power switches, or bidirectional power switches) on the DC-side.

The transformer 104 includes the primary winding and the secondary winding on a magnetic core as shown, and may be operable over MF or HF bands, such as a few kHz to tens of kHz for MF and tens of kHz to MHz for HF. The magnetic core can include ferrite cores, silicon steel, amorphous, or nanocrystalline cores, to provide a few examples, and can be formed of various shapes such as an “E” shape, “EI” shape, “U” shape, “UI” shape, toroidal shape, and other shapes including custom core shapes using building blocks.

The FPPA cell 150 is modular. For example, the FPPA cell 150 can include additional DC-side subcells coupled with the DC-side subcell 106a and the DC port 1, and the FPPA cell 150 can include additional DC-side subcells coupled with the DC-side subcell 108a and the DC port 2. The FPPA cell 150 can include additional AC-side subcells coupled with the AC-side subcell 102a.

The total number of DC-side subcells coupled to the DC port 1 is referred to collectively as DC-side subcell(s) 106, and the total number of DC-side subcells coupled to the DC port 2 is referred to collectively as DC-side subcell(s) 108. The total number of AC-side subcells coupled to the AC port is referred to collectively as AC-side subcell(s) 102. It should be noted that the FPPA system 100A is operable with one AC-side subcell and two DC-side subcells (one DC-side subcell coupled to each DC port). In some embodiments, the FPPA system 100A can be operable with one AC-side subcell and one DC-side subcell coupled to one DC port.

To provide a few examples, the DC-side subcells 106 can include 5 DC-side subcells, 10 DC-side subcells, and other number of DC-side subcells connected in either series or parallel. The DC-side subcells 108 can include 5 DC-side subcells, 10 DC-side subcells, and other number of DC-side subcells connected in either series or parallel. The AC-side subcells 102 can include 5 AC-side subcells, 10 AC-side subcells, and other number of AC-side subcells connected in either series or parallel. The number of DC-side subcells 106 and the number of DC-side subcells 108 can be equal or different depending on application use cases of the FPPA system 100A in the HVDC converter station 1000. The number of AC-side subcells 108 and the number of DC-side subcells 106 and/or the number of DC-side subcells 108 can be equal or different.

Each of the AC-side subcell(s) 102 can include various bridge configurations such as half-bridge, full-bridge, other bridge configurations with bidirectional switches. Each of the DC-side subcell(s) 106 and the DC-side subcell(s) 108 can be embodied as a current doubler rectifier (e.g., current doubler synchronous rectifier) configured to enable the FPPA cell 150 to use or integrate a magnetizing inductance of the transformer 104 as an output filter inductor for bidirectional energy flow between the DC ports and the AC port. In some embodiments, the DC-side subcell(s) 106 and the DC-side subcell(s) 108 can be embodied as rectifiers with various bridge configurations such as half-bridge, full-bridge, or other bridge configurations, and with diode implementations or bidirectional switches. Implementation of current doubler rectifiers can provide increased power density for the FPPA system 100A while also reducing cost, especially because filter inductors, which can be bulky, expensive, and impede power density and efficiency, can be eliminated from the system.

Each of the DC-side subcell(s) 106, the DC-side subcell(s) 108, and the AC-side subcell(s) 102 can include control circuitry, bypass circuitry, and auxiliary circuitry for dynamic reconfiguration and power flow rerouting among the AC and DC ports. For example, each of the DC-side subcell(s) 106, the DC-side subcell(s) 108, and the AC-side subcell(s) 102 can be bypassed when a fault within the subcell is detected therein, based on instructions received from a FPPA controller 10 (also “controller 10” for short), enabling fault-tolerant operation of the FPPA cell 150. “Faults” as described herein may refer to electrical faults or physical faults, such as damage to subcells, submodules, and modules. Additionally, the DC-side subcells 106, the DC-side subcells 108, and the AC-side subcells 102 can be dynamically reconfigured in series or parallel connections based on instructions received from the FPPA controller 10, for achieving various power conversion objectives.

The FPPA system 100A can include the FPPA controller 10 for controlling switching operations of the AC-side subcell(s) 102 and/or the DC-side subcell(s) 106 and 108. The FPPA controller 10 can be embodied as processing circuitry, including memory, configured to control the operation of the FPPA cell 150, with or without feedback. The FPPA controller 10 can be embodied as any suitable type of controller, such as a proportional integral derivative (PID) controller, a proportional integral (PI) controller, or a multi-pole multi-zero controller, among others, to control the operations of the FPPA cell 150. The FPPA controller 10 can be realized using a combination of processing circuitry and referenced as a single controller. It should be appreciated, however, that the FPPA controller 10 can be realized using a number of controllers, control circuits, drivers, and related circuitry, operating with or without feedback.

The FPPA controller 10 can include software or hardware control and can be configured to execute various control algorithms for control of the FPPA cell 150. For one control level, the FPPA controller 10 can be configured to generate switching control signals (e.g., pulse-width modulation (PWM)) for switches of the AC-side subcell(s) 102 and/or the DC-side subcell(s) 106 and 108 for enabling bidirectional power flow between the AC and DC ports and for enabling bypass mechanisms at the cell level. Implementation of bypass mechanisms at the cell level can enable maximum fault tolerance at the lowest modular level. The bypass mechanisms include power semiconductor bypass at the AC ports for the AC-side subcell(s) 102 and the DC ports for the DC-side subcell(s) 106 and 108.

For example, at the AC port, SiC bidirectional MOSFETs (e.g., in full-bridge) for the AC-side subcell(s) 102 can handle bypassing via the bypass circuitry which may be included with each of the AC-side subcell(s) 102 in response to detection of faults by the FPPA controller 10. At each of the DC ports, SiC MOSFET synchronous rectifiers may handle bypassing via the bypass circuitry which may be included with each of the DC-side subcell(s) 106 and 108 in response to detection of faults by the FPPA controller 10. The high switching frequency of SiC MOSFETs, intelligent local gate drivers for fault detection and protection, and high-speed serial link control communication system can enable rapid FPPA VSM bypass protection.

The FPPA controller 10 can be configured to implement mechanical bypass for the DC-side subcell(s) 106, the DC-side subcell(s) 108, and the AC-side subcell(s) 102 of the FPPA cell 150. Once the FPPA controller 10 confirms a fault, a secondary bypass mechanism using mechanical contacts can be engaged, after faulty subcell has been isolated and the energy stored in the faulty DC subcell has been dissipated, for added protection.

In an example embodiment, SiC MOSFETs with embedded schottky barrier diodes (SBDs) on the same chip can be utilized for the switches of the DC-side subcell(s) 106, the DC-side subcell(s) 108, and the AC-side subcell(s) 102, which can reduce switching losses by approximately 59% compared to conventional high voltage SiC MOSFETs with co-packaged separate SBDs. Implementation of the SBDs can enable a high PWM switching frequency, yet maintain substantially low switching losses. The DC filter inductance can be realized, with integrated magnetic design, by the magnetizing inductance of the transformer 104.

For a second control level, the FPPA controller 10 can be configured to implement circuit control by sending a signal or a pulse to the FPPA cell 150 for achieving various power conversion objectives. For example, the FPPA controller 10 can be configured to direct each of the DC-side subcell(s) 106, the DC-side subcell(s) 108, and the AC-side subcell(s) 102 via the control circuitries or bypass circuitries included in each of the DC-side subcell(s) 106, the DC-side subcell(s) 108, and the AC-side subcell(s) 102, to generate or regulate a specific DC voltage at a DC port, generate or regulate a specific AC voltage at an AC port, and/or shape AC input current and/or AC output current. The controller 10 can direct fault-tolerant operation for the FPPA system 100A and the FPPA cell and VSM levels and enable advanced fault protection via current limiting and foldback functionalities at both the AC and DC ports.

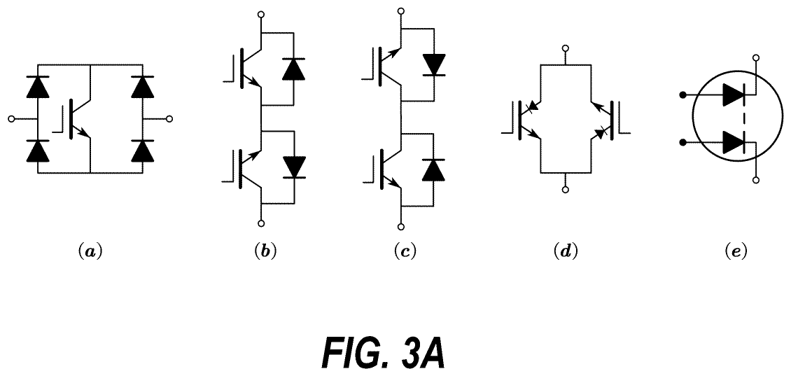

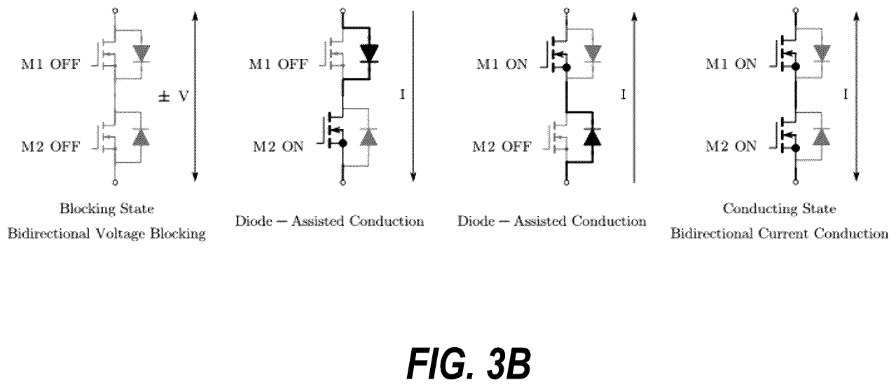

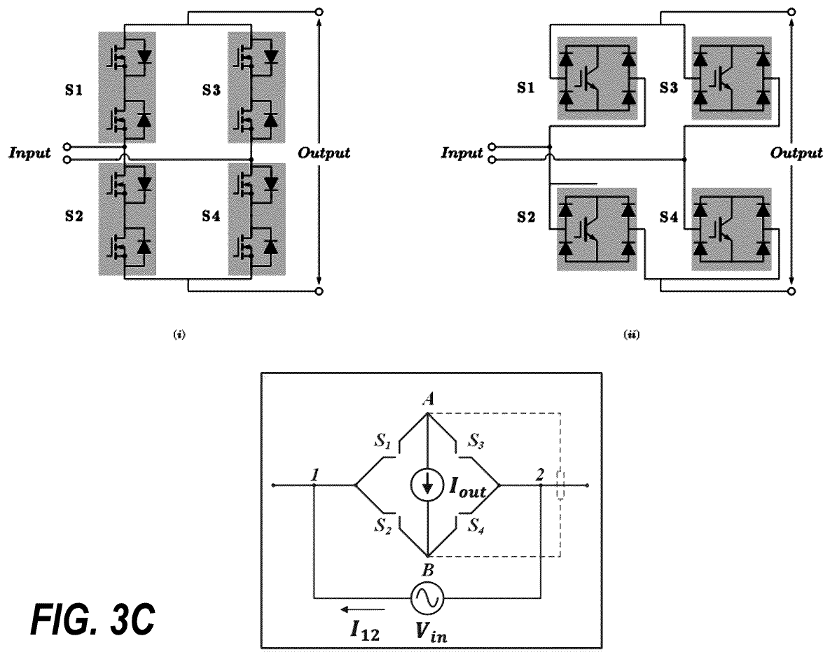

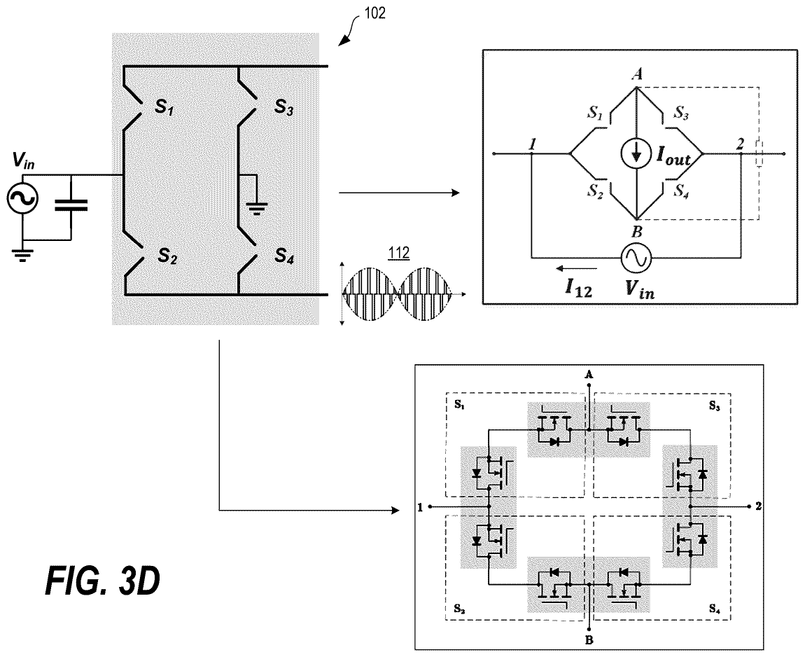

The FPPA cell 150 can serve as a modular building block for various FPPA systems such as the FPPA system 100A. The FPPA cell 150 can be a single-stage direct AC/DC/DC power converter combined with advanced power electronics control, insulated design, thermal management, and packaging technologies, and presents alternative solutions compared to conventional MMC-based HVDC converters. Incorporation of the FPPA cell 150 can provide power density with orders of magnitude of improvement over existing solutions, exceptional efficiency, high reliability and lifespan (through N+M internal redundancy (where “N” denotes a minimum number of subcells needed to operate and “M” denotes the number of redundant subcells added) and fast bypass), and multi-port energy routing capabilities compared to conventional solutions. Additional potential implementations or possibly related variations of the FPPA cell 150 are described or shown in PCT Application No. PCT/US26/13655, filed Feb. 3, 2026, at least at FIGS. 2A, 2B, and 3A-3D of the Drawings and paragraphs [0039]-[0045] of the Specification, the entire disclosure of which is hereby incorporated herein by reference.

The FPPA system 100B in FIG. 2B depicts a same type of FPPA system as the FPPA system 100A but with the IMEC distributed in the magnetic core of the transformer 104 between the AC port and the DC port 1, the AC Port and the DC port 2, and the DC port 1 and the DC port 2. Additionally, the DC-side subcells 106 is shown to include a plurality of DC-side subcells 106a to 106n (with “n” being a whole number), and the DC-side subcells 108 is shown to include a plurality of DC-side subcells 108a to 108n. The IMEC enables a modular and ultra-high power density solution with uniformly distributed voltage stresses for all building blocks at the AC and DC ports.

The IMEC provides high voltage insulation barriers between the AC and DC ports and can be achieved through high dielectric strength polyimide layers (e.g., Kapton®) in the IMEC. Although FIG. 2B shows one gap between the AC port and the DC port 1, for example, the transformer 104 includes a plurality of distributed gaps with polyimide layer therein between each of the AC and DC ports. The polyimide layer or film features extremely high dielectric strength (approximately 150-300 kV/mm) and can provide robust isolation between the AC-side subcell(s) 102, DC-side subcell(s) 106, and the DC-side subcell(s) 108. Additionally, the IMEC enables the FPPA cell 150 to handle HV DC, such as over 1000 kV, as a peak of the high system voltage is distributed between the AC and DC ports.

The FPPA system 100B additionally includes implementations of DC bypass switches for the DC port 1 and the DC port 2 and an AC bypass switch for the AC port. The FPPA controller 10 can be configured to implement mechanical bypass for the DC-side subcell(s) 106, the DC-side subcell(s) 108, and the AC-side subcell(s) of the FPPA cell 150. For example, once the FPPA controller 10 confirms a fault, a secondary bypass mechanism using mechanical contacts such as the DC bypass switches and AC bypass switch can be engaged for added protection.

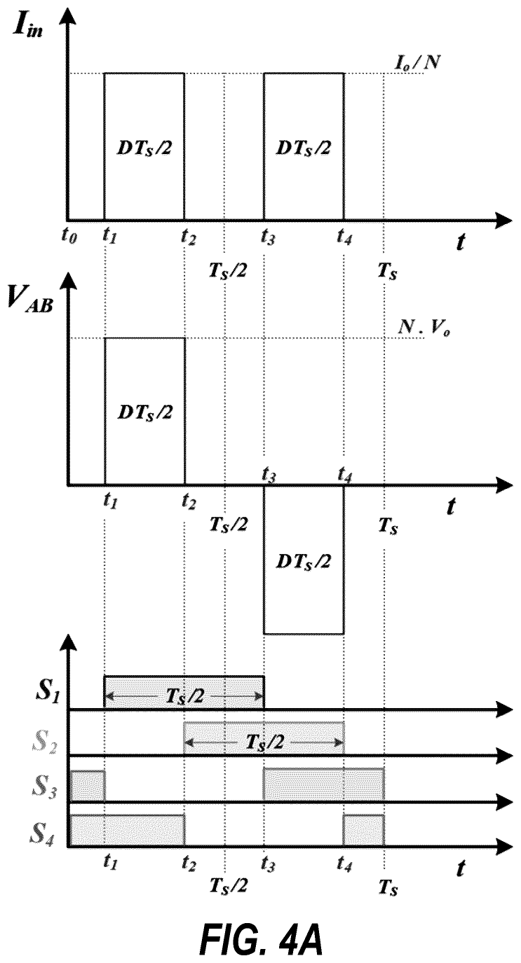

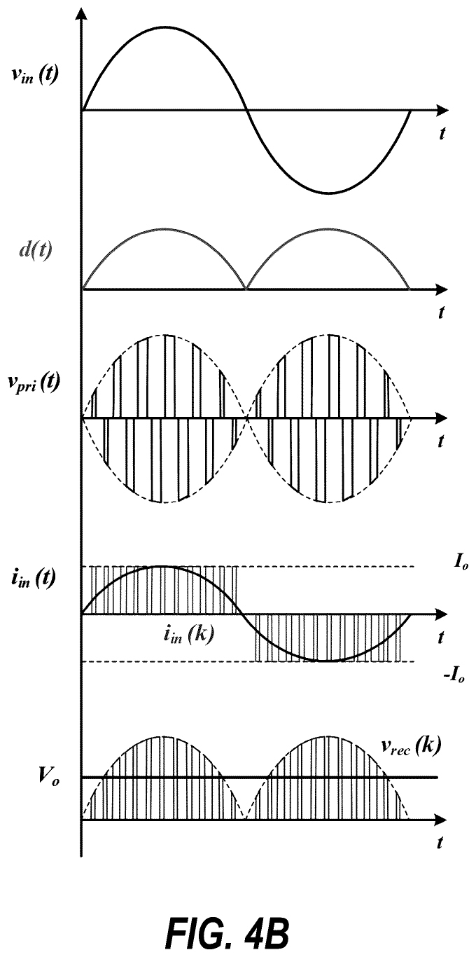

FIG. 3A depicts switch realizations of each switch of the AC-side subcell(s) 102 of the FPPA system 100A and 100B, FIG. 3B depicts representative operating states of a back-to-back MOSFET four-quadrant AC switch for the AC-side subcell(s) 102, FIG. 3C depicts example AC switch bridge realizations for the AC-side subcell(s) 102 and a simplified AC switch bridge defining terminal reference directions and bridge variables used for state classification, and FIG. 3D depicts example operating principles and switch realizations of the AC-side subcell(s) 102. FIG. 4A depicts a switching period timing diagram for switches of the AC-side subcell(s) 102 according to various embodiments.

For the FPPA cell 150 of the FPPA systems 100A and 100B, each controllable input-side switching device (e.g., for the AC-side subcell(s) 102) may be implemented as a four-quadrant bidirectional switch (also referred to herein as an “AC switch”), i.e., a switch capable of conducting current in either direction in the conducting state, and that blocks voltage of either polarity in the blocking state. The AC switch can be realized in multiple ways as shown in FIG. 3A. In (a), the AC switch is implemented with a diode-bridge with a single active switch. In (b), the AC switch is implemented with back-to-back devices in a common-emitter (or common source for MOSFETs) configuration. In (c), the AC switch is implemented with back-to-back devices in a common-collector (or common-drain for MOSFETs) configuration. In (d), the AC switch is implemented with paralleled reverse-blocking IGBTs. In (e), the AC switch is implemented with monolithic bidirectional switches.

In one implementation, the AC switch can be formed using a single actively controlled device in combination with a diode network arranged to provide the required bidirectional current path while maintaining bidirectional voltage blocking at the switch terminals. In other implementations, the AC switch can be realized using two actively controlled devices connected back-to-back, including a back-to-back configuration (common-drain for MOSFETs or common-collector for IGBTs) or a back-to-back configuration (common-source for MOSFETs or common-emitter for IGBTs), where intrinsic diode paths may conduct during selected commutation intervals. Additional realizations include paralleled reverse-blocking IGBTs (RB-IGBTs) and monolithic bidirectional switch devices, including GaN monolithic bidirectional switches (MBDS).

To provide an example, for an AC switch implemented with two MOSFETs back-to-back in a common-drain configuration, each with an intrinsic body diode, the two active devices can be assumed to be M1 and M2. The AC switch can provide four-quadrant capability: when the AC switch is in its blocking state, the AC switch can block either polarity of terminal voltage, and when the AC switch is in its conducting state, the AC switch can carry either polarity of current. Four practical states explain the behavior: 1. Both M1 and M2 are held off, so the switch blocks±V; 2. Both M1 and M2 are held on, so a low-impedance path can exist and current can flow in either direction; 3. One MOSFET is on and the other is off. Depending on the instantaneous polarity and current direction, current may continue through the on device and the intrinsic body diode of the off MOSFET; 4. The complementary case, with the opposite diode path becoming active under the corresponding polarity.

The diode-path states typically appear over short transition intervals (transient behavior). The intended steady states (static behavior) for power processing remain in the bidirectional blocking state and bidirectional conducting state as shown in FIG. 3B.

Referring to FIG. 3C, building on the AC switch behavior described above, an input-side bridge formed from multiple AC switches can be operated using a small set of bridge-level states. For example, the bridge can alternate between an energy transfer state, in which a selected pair of switches applies a non-zero polarity of voltage to the transformer primary, and a bypass state, in which the bridge is set to produce approximately zero applied primary voltage so that the primary current can circulate without net power transfer (corresponds to freewheeling state in the secondary).

Still referring to FIG. 3C, example switch realizations shown in (i) and (ii) for the AC-side subcell(s) 102 are shown. In one implementation, the AC-side subcell(s) 102 can implement back-to-back MOSFETs as shown in (i). In another implementation, the AC-side subcell(s) 102 can implement a diode-bridge and a single active IGBT as shown in (ii). An example switching state table for the AC-side subcell(s) 102 identifying energy transfer and bypass states as a function of switching states (S₁-S₄) is shown below.

TABLE 1
Switching States for Bidirectional Switches

| S1 | S2 | S3 | S4 | State Type | V_{AB} | I₁₂ |
|---|---|---|---|---|---|---|
| 1 | 0 | 0 | 1 | Energy | Vᵢₙ | Iₒᵤₜ |
| 0 | 1 | 1 | 0 | Transfer | −Vᵢₙ | −Iₒᵤₜ |
| 1 | 1 | 0 | 0 | Bypass | 0 | 0 |
| 0 | 0 | 1 | 1 | | 0 | 0 |

Table 1 above shows different switching states for the bidirectional switches S₁, S₂, S₃, and S₄ across different switching intervals t₁-t₂ (S₁ and S₄ on, S₂ and S₃ off), t₂-t₃ (S₁ and S₂ on, S₃ and S₄ off), t₃-t₄ (S₂ and S₃ on, S₁ and S₄ off), and t₄-t₅ (S₃ and S₄ on, S₁ and S₂ off) according to one example. Other switching states may be implemented to achieve similar outcomes in some examples.

In operation, short transition intervals can be inserted between these two states to safely commutate the current and manage energy stored in leakage inductance and device output capacitances. During these intervals, current may circulate locally within the bridge and the transformer for a short duration, and this circulating current is primarily associated with commutation and reactive energy exchange rather than net energy transfer from source to load. These transition intervals can also be used to discharge device output capacitances and/or charge complementary capacitances, thereby enabling soft-switching when conditions allow. Although the device-level conduction paths during these intermediate intervals may be diode-assisted and depend on instantaneous current direction and terminal polarity, the overall switching sequence remains well described by the dominant energy transfer and bypass states.

Over a switching period, the AC-side subcell(s) 102 can alternate between energy transfer states and bypass states. In an energy transfer state, one diagonal pair of bridge positions is in the conducting state so that a non-zero bridge output voltage is applied to the transformer primary (depending on the selected diagonal). In a bypass state, one same-leg pair is placed in the conducting state, clamping the bridge output to approximately zero volts and allowing the transformer leakage current to circulate.

The sequence order is not fixed. Any selected energy-transfer state may be followed by either bypass state, and the next energy-transfer state may be chosen independently, so long as the resulting sequence satisfies the volt-second balance for the transformer with the intended primary voltage pattern and maintains valid commutation. Stated differently, the bridge may transition among the set of energy-transfer and bypass states in any order suitable for the control objective, including interchanging (i) which diagonal pair is used for energy-transfer and (ii) which same-leg pair is used for bypass, as long as the volt-second balance is achieved for the transformer within consecutive energy-transfer and bypass states. In addition, the labeling of the bridge input and output terminals can be swapped, without changing the underlying operation principle, provided the associated voltage and current directions are updated consistently. Certain switching combinations are excluded because they create a direct conduction path across the input source. For example, S1 and S3 ON simultaneously can create a short-circuit condition on the AC port of that subcell.

As one non-limiting example, consider a transition from the energy-transfer state (S1, S4 ON) to the bypass state (S1, S2 ON). In this transition, the bridge moves from a condition in which the diagonal pair associated with AC switches 1 and 4 applies a non-zero primary voltage to one in which AC switches 1 and 2 clamp the bridge output to approximately zero voltage. Because the leakage inductance is continuous and may be nonzero at the transition, commutation is implemented using short intermediate intervals in which one AC switch enters diode-assisted conduction while the other is enabled, thereby transferring current without forcing an abrupt current discontinuity. During these intermediate intervals, the circulating current can charge and discharge device output capacitances, enabling soft-switching (e.g., ZVS) when current polarity and magnitude are favorable.

Assume each bridge position Sₖ is implemented as a four-quadrant AC switch using back-to-back MOSFETs Sₖₐ and S_{kb}. The table below illustrates one representative commutation order. Other equivalent orders may be used depending on the current polarity and the desired soft-switching condition. The commutation sequence shown below is illustrated for the input voltage in the positive half-line cycle and leakage/transformer primary current greater than zero.

TABLE 2
Example Commutation Sequence for Transition from (S1, S4) to (S1, S2)

| | S₁ | | S₂ | | S₄ | | |
|---|---|---|---|---|---|---|---|
| Commutation Step | S₁ₐ | S_{1b} | S₂ₐ | S_{2b} | S₄ₐ | S_{4b} | Remark |
| t₀ → t₁: Initial | 1 | 1 | 0 | 0 | 1 | 1 | Channel conduction |
| energy-transfer | | | | | | | through S₁ and S₄ |
| t₁ → t₂: Start | 1 | 1 | 0 | 0 | 0 | 1 | S₄ enters diode-assisted |
| transfer to bypass, | | | | | | | mode |
| “open” S₄ partially | | | | | | | |
| t₂ → t₃: Introduce | 1 | 1 | 0 | 1 | 0 | 1 | Current continues |
| bypass leg partially | | | | | | | through the diode- |
| | | | | | | | assisted path in S₄(diode |
| | | | | | | | of S₄ₐ forward-biased) |
| t₃ → t₄: Release | 1 | 1 | 0 | 1 | 0 | 0 | Current transfers to the |
| outgoing leg | | | | | | | diode-assisted path in S₂ |
| (remove S₄ fully) | | | | | | | |
| t₄ → t₅: Complete | 1 | 1 | 1 | 1 | 0 | 0 | Channel conduction |
| transition to bypass | | | | | | | through S₁ and S₂; ZVS |
| state | | | | | | | achieved for S₂ₐ |

According to an exemplary implementation, bidirectional switches S₁, S₂, S₃, and S₄ of the AC-side subcell(s) 102 can be embodied as commercial-off-the-shelf half-bridge MOSFET modules (e.g., SiC MOSFET modules) in back-to-back configurations as depicted in FIG. 3D. In one example, the switching frequency of the AC-side subcell(s) 102 can range from approximately 10 kHz to MHz. In other examples, the bidirectional switches S₁, S₂, S₃, and S₄ may be embodied as eight single-switch power modules with each two single-switch power modules connected as a pair in a common-emitter configuration or a common-collector configuration.

The controller 10 can be configured to provide switching control signals for the bidirectional switches S₁, S₂, S₃, and S₄, which can be switched at a high frequency to provide sinusoidal input current and power factor correction (PFC) rectification. The controller 10 can be configured to control the AC-side subcell(s) 102, so that the AC switch bridge 102 effectively chops the Vᵢₙ to high frequency pulses within a sinusoidal LF envelope and transmits the high frequency pulses to the transformer 104. Additionally, the pulse-width of the high frequency pulse train can be sinusoidal with respect to time, meaning that the pulse-width can be sinusoidally modulated (sinusoidal pulse width modulation (SPWM)). This control methodology is described below.

The FPPA cell 150 can be controlled by varying energy-transfer and bypass durations of the AC-side subcell(s) 102 within each switching period and across the line cycle to satisfy two objectives simultaneously: (i) regulation of the DC output voltage, and (ii) shaping of the AC input current. This timing variable includes the primary control degree of freedom of the cell 150. From a control viewpoint, the AC-side subcell(s) 102 can produce a switched version of the input such that the resulting average voltage after rectification is a fraction of the input voltage, so the output can be regulated in a manner analogous to a buck converter (e.g., isolated buck converter). That is, the effective output voltage can be the available input voltage level for any given operating point. Transformer scaling can be introduced separately, since the turns ratio can be set to step-down, 1:1, or step-up, depending on the application.

The controller 10 can be configured to control the AC switch bridge 102 to alternately shift between an energy transfer state and a bypass state across the switching intervals mentioned above to facilitate conversion of the AC input to the DC output. Referring to Table 1, in the first switching interval t₁-t₂ corresponding to the energy transfer state, the controller 10 is configured to turn on the first bidirectional switch S₁ and the fourth bidirectional switch S₄ and turn off the second bidirectional switch S₂ and the third bidirectional switch S₃. In the second switching interval t₂-t₃ corresponding to the bypass state, the controller 10 is configured to turn on the first bidirectional switch S₁ and the second bidirectional switch S₂ and turn off the third bidirectional switch S₃ and the fourth bidirectional switch S₄, or turn on the third bidirectional switch S₃ and the fourth bidirectional switch S₄ and turn off the first bidirectional switch S₁ and the second bidirectional switch S₂.

In the third switching interval t₃-t₄ corresponding to the energy transfer state, the controller 10 is configured to turn on the second bidirectional switch S₂ and the third bidirectional switch S₃ and turn off the first bidirectional switch S₁ and the fourth bidirectional switch S₄. In the fourth switching interval t₄-t₅ corresponding to the bypass state, the controller 10 is configured to turn on the third bidirectional switch S₃ and the fourth bidirectional switch S₄ and turn off the first bidirectional switch S₁ and the second bidirectional switch S₂, or turn on the first bidirectional switch S₁ and the second bidirectional switch S₂ and turn off the third bidirectional switch S₃ and the fourth bidirectional switch S₄.

The energy transfer state is associated with the AC input Vᵢₙ being connected to the primary winding of the transformer 104, and the bypass state is associated with the Vᵢₙ being disconnected from the primary winding of the transformer 104. The controller 10 can be configured to cause the AC-side subcell(s) 102 to alternately shift between the energy transfer state and the bypass state across the above-mentioned switching intervals of a switching cycle. This shifting between the energy transfer state and the bypass state can be repeated across one or more switching cycles to cause the AC-side subcell(s) 102 to generate a quasi-square wave voltage waveform signal 112 with a sinusoidal LF modulation envelope, which can be transmitted to the input or primary winding of the transformer 104.

Referring to FIG. 4A, the energy transfer state is associated with overlap of duty cycles between the first bidirectional switch S₁ and the fourth bidirectional switch S₄ for the first switching interval t₁-t₂ and overlap of duty cycles between the second bidirectional switch S₂ and the third bidirectional switch S₃ for the third switching interval t₃-t₄. The bypass state is associated with overlap of duty cycles between the first bidirectional switch S₁ and the second bidirectional switch S₂ for the second switching interval t₂-t₃ and overlap of duty cycles between the third bidirectional switch S₃ and the fourth bidirectional switch S₄ for the fourth switching interval t₄-t₅. As the duty cycle and the duty cycle overlaps for the bidirectional switches S₁, S₂, S₃, and S₄ change over the line cycle, the duration of the energy transfer states can be modified to obtain a desired sinusoidal input current waveform.

To provide an example of cell-level control implementable via the controller 10, consider a representative switching period Tₛ (instantaneous input voltage vᵢₙ(t) can be approximated as a constant DC voltage Vᵢₙ as Tₛ<<T_{f}, the line cycle/period. Over Tₛ, the bridge timing determines when a non-zero primary excitation is applied and, therefore, when the transformer secondary and the rectifier devices conduct, setting the instantaneous voltages presented to the output filter. During the complementary interval, the primary excitation is clamped near zero and the output filter freewheels, with the inductor current remaining continuous.

As a result, the output filter inductor experiences alternating inductor-voltage conditions, and its average volt-seconds over a switching period must balance in steady state. Using an effective duty, D, the fraction of Tₛ for which the energy transfer states are active, the switching-cycle averaged output relation can be written in buck form as:

$${V}_{O} = D \cdot \frac{{V}_{in}}{N} , \qquad ( Eq . 1 )$$

where Vₒ is the regulated DC output voltage, N is the transformer turns ratio. When the secondary is driven, the source supplies current that is approximately the output inductor current reflected through the transformer (e.g., the transformer 104). When it is not driven, the source contribution is reduced, and the output filter current circulates locally. This can be expressed as:

$${i}_{in} ( t ) = d ( t ) \cdot \frac{{I}_{L} ( t )}{N} , \qquad ( Eq . 2 )$$

where iᵢₙ(t) is the instantaneous current drawn from the AC source, i_{L} (t) is the output filter inductor current, and d(t) is the instantaneous switching/duty function.

To obtain a sinusoidal input current, the duty-cycle function is varied over the line-cycle so that iᵢₙ(t) tracks a sinusoidal reference (waveform shaping). One representative form is:

$$d ( t ) = \frac{{l}_{o}}{N} \vert sin ( {ω}_{L} t ) \vert , \qquad ( Eq . 3 )$$

where ω_{L} is the line angular frequency, and Iₒ is the DC output current (approximately equal to the average of i_{L}(t) in continuous conduction). With this, the energy transfer duration within each switching period is increased and decreased over half the line cycle so that the instantaneous input current tracks the desired sinusoidal shape in each half line cycle.

FIG. 4B depicts representative waveforms over a line cycle with respect to the FPPA systems 100A and 100B. Example parameters include input voltage vᵢₙ(t), duty cycle function d(t), resulting line-frequency amplitude-modulated bipolar MF/HF transformer primary voltage vₚᵣᵢ(t), switched input current iᵢₙ(k) and corresponding switching cycle average iᵢₙ(t), and switched secondary-side rectified waveform v_{rec}(k), leading to a regulated DC output Vₒ.

When the instantaneous input current tracks the desired sinusoidal shape in each half line cycle as discussed above during operation of the FPPA cell 150, at near or at the same time, because the output voltage is set by switching-cycle volt-second balance, the line-cycle average of the effective duty remains in a similar buck-type relationship. In this single-stage isolated converter (e.g., FPPA cell 150), the switching actions can cause the input voltage to be reflected to the output and the output current to be reflected to the input, consistent with the expectations in the absence of energy storage elements.

The transformer primary voltage waveform is a line-frequency amplitude-modulated bipolar MF/HF pulse train (quasi-square wave) with varying pulse width, derived from the AC input voltage. The corresponding AC input current waveform appears as a single-polarity MF/HF pulse train over each line half-cycle with varying pulse width, limited by the output current reflected to the input.

On the DC side, the output LC filter network of the FPPA cell 150 can be selected to attenuate the single-phase ripple component (2ω_{L} component). Consequently, the same filter design can inherently provide strong attenuation of the MF/HF switching ripple.

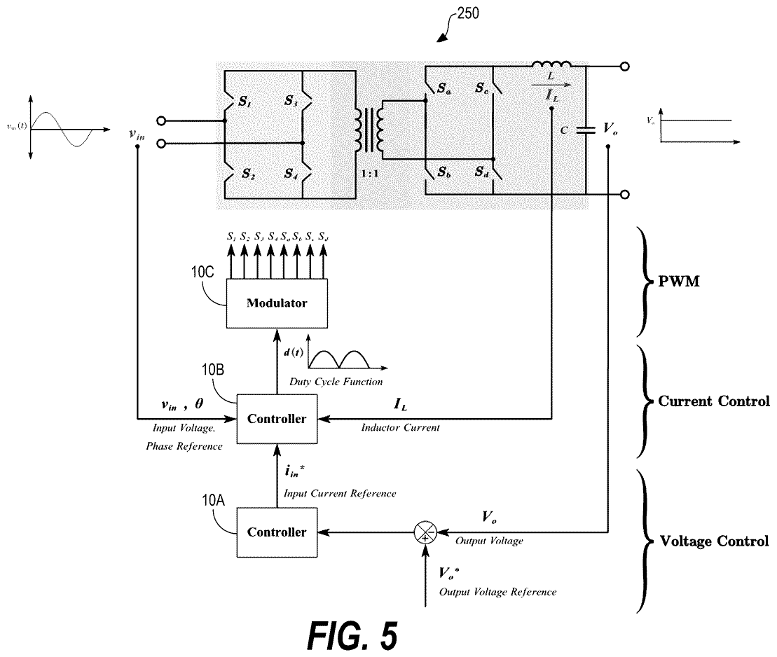

FIG. 5 depicts a control loop diagram for PWM generation for an FPPA cell 250 according to various embodiments. The FPPA cell 250 is similar to the FPPA cell 150 but includes one AC port and one DC port as shown. Additionally, a full-bridge rectifier with four active switches is coupled to the secondary side of the transformer. The operation of the controller 10 for controlling the FPPA cell 250 is applicable to the FPPA cell 150, as described below.

The controller 10 can include a controller 10A, a controller 10B, and a modulator 10C. The modulator 10C can convert a commanded duty-cycle function d(t) into PWM switching signals for S₁-S₄, which are delivered to the corresponding gate-drive circuitry. An inner current control loop can shape the input current waveform by regulating d(t) using the line-voltage phase reference and measured current (e.g., inductor current). An outer voltage control loop can regulate the DC output voltage Vₒ by adjusting the current-reference magnitude (or equivalent scaling) based on the error between the measured output voltage and the reference DC output voltage. In the illustrated configuration, the primary bridge timing provides a single control degree of freedom. If the secondary rectification is implemented as an active rectifier, this implementation can introduce an additional independent control degree of freedom on the secondary side.

Grid interconnection typically requires the line-frequency input current to be sinusoidal and to satisfy applicable power quality constraints, while the MF/HF switching components may need to be sufficiently attenuated so these components are not injected into the source. Accordingly, a capacitive input filter can be included to attenuate MF/HF current components so that the grid-facing current transitions from a switched pulse train waveform produced by the switch bridge to a substantially sinusoidal line-frequency current at the AC terminals. Because this capacitive element can introduce a reactive current component, the switched input current of the switch bridge can be compensated for this phase shift in anticipation. The duty cycle function can include an explicit phase shift term

$$d ( t ) = \frac{{l}_{o}}{N} \vert sin ( {ω}_{L} t + θ ) \vert , \qquad ( Eq . 4 )$$

where θ is selected to offset the filter-induced phase displacement (and thereby achieve the desired power factor (unity)).

Including the phase term θ in the duty function can shift the input current relative to the input voltage. Depending on the operating point, portions of the line cycle can require current of opposite polarity relative to the voltage polarity. Accordingly, the cell 150 may need to accommodate reverse power flow in brief intervals, necessitating an actively controlled secondary stage (allowing bidirectional current flow).

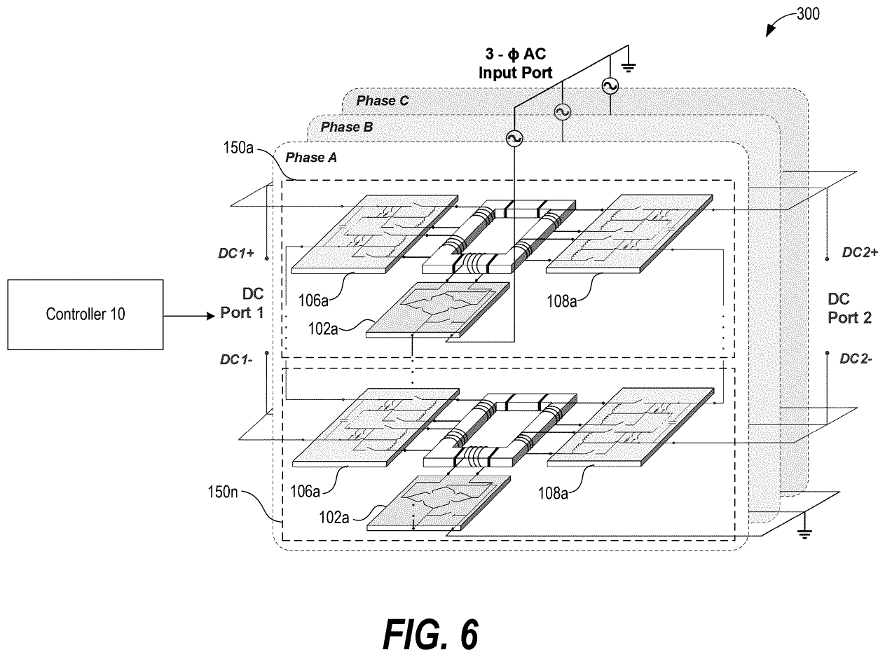

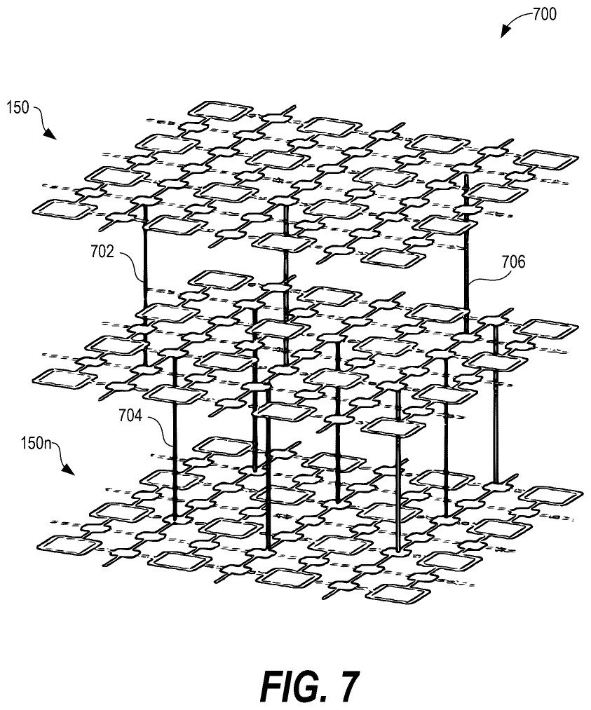

FIG. 6 depicts a schematic of an example multi-phase FPPA system 300 for enabling bidirectional power flow, and FIG. 7 depicts switch interconnect fabric of the multi-phase FPPA system 300 interconnecting AC-side subcells among multiple FPPA cells to each other and DC-side subcells among multiple FPPA cells to each other, according to various embodiments. The multi-phase FPPA system 300 can be implemented in both HVDC and MVDC power converter systems and applications and can include multiple FPPA cells 150a to 150n (with “n” being a whole number) coupled together in a reconfigurable manner at AC and DC ports for each phase leg of the multi-phase FPPA system 300. Each of the FPPA cells 150a to 150n are substantially similar to the FPPA cell 150 shown in the FPPA systems 100A and 100B. The various reconfigurable coupling configurations are described in further detail below.

As described with respect to the FPPA systems 100A and 100B, each FPPA cell can be coupled between an AC port and two DC ports (DC port 1 and DC port 2) as illustrated. However, the AC-side subcell(s) 102 (e.g., AC-side subcells 102a to 102n with “n” being a whole number) for each FPPA cell (e.g., cell 150 or cell 150n) can be expanded to include multiple AC-side subcells that are connected in parallel or series at the AC port within the cell. Additionally, the DC-side subcell(s) 106 (e.g., DC-side subcells 106a to 106n) for each FPPA cell can be expanded to include multiple DC-side subcells that are connected in parallel or series at the DC port 1 within the cell, and the DC-side subcell(s) 108 (e.g., DC-side subcells 108a to 108n) for each FPPA cell can be expanded to include multiple DC-side subcells that are connected in parallel or series at the DC port 2 within the cell.

In an example configuration for HVDC handling, for each cell, the AC-side subcells 102 may be connected in parallel to the AC port, the DC-side subcells 106 may be connected in series to the DC port 1, and the DC-side subcells 108 may be connected in series to the DC port 2. However, the FPPA system 300 is not limited thereto and the AC-side subcells 102, the DC-side subcells 106, and the DC-side subcells 108 for each cell can be dynamically recoupled into other configurations based on instructions received from the controller 10.

Multiple FPPA cells within a phase leg can be coupled to each other in various configurations. Referring to FIG. 7, the FPPA system 300 can include a switch interconnect fabric 700 for interconnecting the FPPA cells 150 to 150n to each other via interconnect structures 702, 704, and 706. The switch interconnect fabric 700 (also referred to as an interconnect network, switching fabric, or switch matrix) can be configured to provide selectable electrical coupling among power switches and/or converter cells. The switch interconnect fabric can include a plurality of conductive interconnects (e.g., busbars, backplane conductors, cables, printed circuit board traces, or combinations thereof) and a plurality of controllable switching elements (e.g., semiconductor switches, contactors, relays, solid-state switches, or combinations thereof) arranged to form multiple selectable current paths.

In some examples, the switch interconnect fabric 700 can include a plurality of fabric nodes and fabric links. Each converter cell can be coupled to the switch interconnect fabric via one or more cell terminals (e.g., an AC terminal, one or more DC terminals, and/or internal midpoints). The fabric links can include one or more conductors providing electrical connectivity between fabric nodes, and the switch interconnect fabric can further include one or more selectable coupling elements positioned on the fabric links and/or at the fabric nodes. The selectable coupling elements can be controlled to open, close, or modulate coupling between selected nodes to implement a commanded topology.

In some examples, the switch interconnect fabric 700 can be configured to interconnect power switches among different power converter cells to enable (i) reconfiguration of cell-to-cell connectivity (e.g., series, parallel, bypassed, inserted), (ii) selective routing of current between cells, and/or (iii) isolation of a cell or switch from one or more ports. For example, the switch interconnect fabric 700 can selectively couple a first node of a first converter cell to a corresponding node of a second converter cell, while decoupling that first node from a third converter cell, based on a commanded operating mode.

The switch interconnect fabric 700 shown in FIG. 7 is provided for representative purposes only. Other interconnect fabrics having different numbers, arrangements, and/or types of interconnections and switching elements may be used without departing from the scope of the present disclosure. In the example shown, the interconnect structure 702 can couple the AC-side subcells 102 among the multiple FPPA cells (e.g., cells 150 to 150n) to each other, the interconnect structure 704 can couple the DC-side subcells 106 among the multiple FPPA cells to each other, and the interconnect structure 706 can couple the DC-side subcells 108 among the multiple FPPA cells to each other.

The controller 10 can be configured to direct the switch interconnect fabric 700 to dynamically reconfigure coupling configurations of the AC-side subcells 102 among the multiple FPPA cells (e.g., cells 150 to 150n for phase A, B, or C) between series and parallel configurations at the AC port. The controller 10 can be configured to direct the switch interconnect fabric 700 to dynamically reconfigure coupling configurations of the DC-side subcells 106 among the multiple FPPA cells between series and parallel configurations at the DC port 1. The controller 10 can be configured to direct the switch interconnect fabric 700 to dynamically reconfigure coupling configurations of the DC-side subcells 108 among the multiple FPPA cells between series and parallel configurations at the DC port 2.

The controller 10 can also be configured to direct the switch interconnect fabric 700 to bypass certain cells among the multiple FPPA cells in response to detection of faults. For example, the controller 10 may detect a fault at the FPPA cell 150 and can direct the switch interconnect fabric 700 to bypass the cell 150 so that energy would not flow therein and be rerouted to other cells in the FPPA system 300. Any power converter cell or FPPA cell in which a fault is detected can be bypassed or shorted for series connections (e.g., by shorting the two AC terminals for the AC side or shorting the two DC terminals on the DC side). For power converter cells connected in parallel, any power converter cell or cell components can be isolated or disconnected (e.g., by disconnecting corresponding AC terminals for the AC side or disconnecting corresponding DC terminals on the DC side).

Each phase leg (e.g., corresponding to phase A, phase B, and phase C) may generate single-phase ripple power and in three-phase operation as shown by the system 300, these single-phase ripple powers may be cancelled out with each other by coupling in parallel the AC input ports of each of the phase legs, the DC port 1 of each of the phase legs, and the DC port 2 of each of the phase legs.

The following provides exemplary embodiments of an FPPA cell or FPPA system. In one example, multiple subcells of an FPPA cell can be connected together in parallel and series on the primary and secondary sides, respectively, of a transformer (e.g., the transformer 104) to create a submodule (e.g., implementable in the HVDC converter station 1000 or MVDC converter systems) with matched AC and DC port voltages (e.g., 2 kV). Multiple submodules can be stacked together on both the AC and DC ports in the same tower to create a module (e.g., rated at 30+ kV). A multi-port or multi-phase FPPA system on a high voltage (e.g., ±525 kV) DC grid can be created with FPPA submodules connected in series in the AC port and DC ports. Bypass at AC and DC ports at FPPA cell and VSM levels are designed to achieve fault-tolerant operation and high system reliability, as discussed above.

Some advantages of the FPPA systems 100 (100A and 100B) and 300 include replacement of LF transformers as compared to state-of-the-art (SOTA) HVDC converters. For example, traditional 60 Hz transformers can be replaced with compact, HF (e.g., 20 kHz) transformers. Bulky, single-phase “flying” capacitors can be eliminated. Each VSM's large capacitors can be replaced with significantly smaller three-phase DC link capacitors for example. The FPPA-based single-stage direct power conversion topology inherently cancels double LF ripple power when three-phase DC outputs combine at the DC port.

Insulation distances are significantly reduced. The described circuitry, insulation, and packaging designs minimize insulation gaps between FPPA cells, submodules, and modules at the AC and DC ports. The single-stage AC/DC/DC topology can ensure uniform voltage stress distribution, similar to conventional MMC-based HVDC converters. Only LV insulation (e.g., 500 V) may be required between FPPA Cells (e.g., FPPA cells 150a to 150n), while only MV insulation (e.g., 2 kV and 30 kV) may be required between FPPA submodules and modules based on implementation of bulk ceramic housing. Bulk ceramic housing has a 3-6× higher dielectric strength than air. Energy transfer between AC and DC ports can occur via HF transformers with galvanic isolation, eliminating direct electrical connections found in MMC-based HVDC converters.

The high system voltage insulation boundary is established through IMEC which features high dielectric strength (150-300 kV/mm). The insulation materials, system, and structure can be designed, modeled, and tested—especially for partial discharge under AC (sinusoidal and pulse-width-modulated) and DC conditions to ensure reliability, longevity (25-40 years), and environmental sustainability.

Large air-core arm inductors can be eliminated. Unlike MMC-based HVDC converters, an FPPA-based single-stage direct AC/DC/DC power conversion circuit does not require these inductors. Additionally, DC port filter inductors are unnecessary, as their function is integrated into the magnetizing inductance of the HF transformer using a current doubler rectifier and advanced magnetic design.

The features, structures, or characteristics described above may be combined in one or more embodiments in any suitable manner, and the features discussed in the various embodiments are interchangeable, if possible. In the following description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although the relative terms such as “on,” “below,” “upper,” and “lower” are used in the specification to describe the relative relationship of one component to another component, these terms are used in this specification for convenience only, for example, as a direction in an example shown in the drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

Terms such as “top,” “bottom,” “side,” “front,” “back,” “right,” “rear,” and “left” are not intended to provide an absolute frame of reference. Rather, the terms are relative and are intended to identify certain features in relation to each other, as the orientation of structures described herein can vary. The terms “comprising,” “including,” “having,” and the like are synonymous, are used in an open-ended fashion, and do not exclude additional elements, features, acts, operations, and so forth. Also, the term “or” is used in its inclusive sense, and not in its exclusive sense, so that when used, for example, to connect a list of elements, the term “or” means one, some, or all of the elements in the list.

When two components are described as being “coupled to” or “connected to” each other, the components can be electrically coupled or connected to each other, with or without other components being electrically coupled and intervening between them. When two components are described as being “directly coupled to” or “directly connected to” each other, the components can be electrically coupled or connected to each other, without other components being electrically coupled between them.

In this specification, the terms such as “a,” “an,” “the,” and “said” are used to indicate the presence of one or more elements and components. The terms “comprise,” “include,” “have,” “contain,” and their variants are used to be open ended, and are meant to include additional elements, components, etc., in addition to the listed elements, components, etc. unless otherwise specified in the appended claims. If a component is described as having “one or more” of the component, it is understood that the component can be referred to as “at least one” component.

The terms “first,” “second,” etc. are used only as labels, rather than a limitation for a number of the objects. It is understood that if multiple components are shown, the components may be referred to as a “first” component, a “second” component, and so forth, to the extent applicable.

The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

Disjunctive language such as the phrase “at least one of X, Y, or Z,” unless specifically stated otherwise, is otherwise understood with the context as used in general to present that an item, term, etc., can be either X, Y, or Z, or any combination thereof (e.g., X; Y; Z; X or Y; X or Z; Y or Z; X, Y, or Z; etc.). Thus, such disjunctive language is not generally intended to, and should not, imply that certain embodiments require at least one of X, at least one of Y, or at least one of Z to each be present.

One or more microprocessors, microcontrollers, or DSPs can execute software to perform the control aspects of the embodiments described herein, such as the control aspects performed by the FPPA controller 10. Any software or program instructions can be embodied in or on any suitable type of non-transitory computer-readable medium for execution. Example computer-readable mediums include any suitable physical (i.e., non-transitory or non-signal) volatile and non-volatile, random and sequential access, read/write and read-only, media, such as hard disk, floppy disk, optical disk, magnetic, semiconductor (e.g., flash, magneto-resistive, etc.), and other memory devices. Further, any component described herein can be implemented and structured in a variety of ways. For example, one or more components can be implemented as a combination of discrete and integrated analog and digital components.

The above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

1. A modular field programmable power array (FPPA) system, comprising:
an FPPA cell comprising:
an alternating current (AC) port, a first direct current DC port, and a second DC port;
a transformer;
an AC-side subcell coupled between the AC port and the transformer;
a first DC-side subcell coupled between the first DC port and the transformer;
a second DC-side subcell coupled between the second DC port and the transformer; and
an FPPA controller configured to control interconnections of the AC-side subcell, the first DC-side subcell, and the second DC-side subcell of the FPPA cell with a second FPPA cell.

2. The modular FPPA system of claim 1, wherein the FPPA cell further comprises:
an additional AC-side subcell coupled between the AC port and the transformer;
an additional DC-side subcell coupled between the first DC port and the transformer; and
an additional DC-side subcell coupled between the second DC port and the transformer.

3. The modular FPPA system of claim 2, further comprising a switch interconnect fabric, wherein the FPPA controller is further configured to:
direct the switch interconnect fabric to interconnect the AC-side subcell and the additional AC-side subcell between the AC port and the transformer in a first connection configuration;
direct the switch interconnect fabric to interconnect the first DC-side subcell and the additional DC-side subcell between the first DC port and the transformer in a second connection configuration; and
direct the switch interconnect fabric to interconnect the second DC-side subcell and the additional DC-side subcell between the second DC port and the transformer in a third connection configuration.

4. The modular FPPA system of claim 3, wherein the first connection configuration is a series configuration, the second connection configuration is a series configuration, and the third connection configuration is a series configuration.

5. The modular FPPA system of claim 3, wherein the first connection configuration is a parallel configuration, the second connection configuration is a parallel configuration, and the third connection configuration is a parallel configuration.

6. (canceled)

7. (canceled)

8. The modular FPPA system of claim 1, wherein:
the AC-side subcell is a full-bridge with bidirectional switches; and
the first DC-side subcell and the second DC-side subcell are current doubler rectifiers.

9. (canceled)

10. The modular FPPA system of claim 1, wherein:
the AC-side subcell of the FPPA cell and an AC-side subcell of the second FPPA cell are connected in series or parallel;
the first DC-side subcell of the FPPA cell and a first DC-side subcell of the second FPPA cell are connected in series or parallel; and
the second DC-side subcell of the FPPA cell and a second DC-side subcell of the second FPPA cell are connected in series or parallel.

11. A modular field programmable power array (FPPA) system, comprising:
an FPPA cell comprising a first transformer, a first AC-side subcell, a first DC-side subcell, and a second DC-side subcell;
a second FPPA cell comprising a second transformer, a second AC-side subcell, a third DC-side subcell, and a fourth DC-side subcell;
a switch interconnect fabric; and
an FPPA controller configured to:
direct the switch interconnect fabric to interconnect the first and second AC-side subcells to an AC port in a first connection configuration;
direct the switch interconnect fabric to interconnect the first and third DC-side subcells to a first DC port in a second connection configuration; and
direct the switch interconnect fabric to interconnect the second and fourth DC-side subcells to a second DC port in a third connection configuration.

12. (canceled)

13. The modular FPPA system of claim 11, wherein the first connection configuration is a parallel configuration, the second connection configuration is a parallel configuration, and the third connection configuration is a parallel configuration.

14. The modular FPPA system of claim 11, wherein the first connection configuration is a series configuration, the second connection configuration is a parallel configuration, and the third connection configuration is a parallel configuration.

15. The modular FPPA system of claim 11, wherein the first connection configuration is a parallel configuration, the second connection configuration is a series configuration, and the third connection configuration is a series configuration.

16. (canceled)

17. The modular FPPA system of claim 11, wherein:
the FPPA cell is implemented in a first submodule;
the second FPPA cell is implemented in a second submodule; and
the second FPPA cell is stacked on the FPPA cell to form a module.

18. The modular FPPA system of claim 11, wherein:
the modular FPPA system is a multi-phase system;
the FPPA cell and the second FPPA cell are components of a first phase leg of the multi-phase system;
the multi-phase system comprises a second phase leg and a third phase leg;
the second phase leg comprises an FPPA cell comprising a transformer, a first AC-side subcell, a first DC-side subcell, and a second DC-side subcell, the FPPA cell coupled to a second AC port and between the first and second DC ports;
the third phase leg comprises an FPPA cell comprising a transformer, a first AC-side subcell, a first DC-side subcell, and a second DC-side subcell, the FPPA cell coupled to a third AC port and between the first and second DC ports; and
the FPPA cell and the second FPPA cell of the first phase leg, the FPPA cell of the second phase leg, and the FPPA cell of the third phase leg.

19. The modular FPPA system of claim 18, wherein the FPPA controller is further configured to:
direct the switch interconnect fabric to interconnect the first DC-side subcell of the second phase leg, the first DC-side subcell of the third phase leg, and the first and third DC-side subcells of the first phase leg in series to the first DC port; and
direct the switch interconnect fabric to interconnect the second DC-side subcell of the second phase leg, the second DC-side subcell of the third phase leg, and the second and fourth DC-side subcells of the first phase leg in series to the second DC port.

20. The modular FPPA system of claim 11, wherein:
the AC-side subcells coupled to the AC port are full bridges with bidirectional switches;
the DC-side subcells coupled to the first DC port are current doubler rectifiers; and
the DC-side subcells coupled to the second DC port are current doubler rectifiers.

21. A modular field programmable power array (FPPA) system, comprising:
a first FPPA cell comprising a transformer, an AC-side subcell and a DC-side subcell;
a second FPPA cell comprising a transformer, an AC-side subcell and a DC-side subcell;
a switch interconnect fabric; and
an FPPA controller configured to:
direct the switch interconnect fabric to interconnect the AC-side subcells of the first FPPA cell and the second FPPA cell to an AC port in a first connection configuration; and
direct the switch interconnect fabric to interconnect the DC-side subcells of the first FPPA cell and the second FPPA cell to a DC port in a second connection configuration.

22. The modular FPPA system of claim 21, wherein the first connection configuration is a series configuration, and the second connection configuration is a series configuration.

23. The modular FPPA system of claim 21, wherein the first connection configuration is a parallel configuration, and the second connection configuration is a parallel configuration.

24. The modular FPPA system of claim 21, wherein the first connection configuration is a series configuration, and the second connection configuration is a parallel configuration.

25. The modular FPPA system of claim 21, wherein the first connection configuration is a parallel configuration, and the second connection configuration is a series configuration.
